(19) United States
(12) Patent Application Publication
(10) Pub. No.: US 2006/0189126 A1
(43) Pub. Date: Aug. 24, 2006

(54) Method of forming semiconductor device having epitaxial contact plug connecting stacked transistors

(76) Inventors: Ki-Hoon Jang, Seoul (KR); Yong-Sun Ko, Suwon-si (KR); Kyung-Hyun Kim, Seoul (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/269,602

(22) Filed: Nov. 9, 2005

(30) Foreign Application Priority Data
Nov. 9, 2004 (KR) 2004-90749

(51) Int. Cl. H01L 21/4763

(52) U.S. Cl. 438/629

(57) ABSTRACT

A method of forming an epitaxial contact plug in a semiconductor device comprises forming an insulating interlayer on a semiconductor substrate, forming a mushroom-shaped epitaxial plug in an opening of the insulating interlayer, forming a buffer layer on the epitaxial plug and the insulating interlayer, and planarizing epitaxial plug and the insulating interlayer using a chemical mechanical polishing (CMP) process.

### BACKGROUND OF THE INVENTION

1. Field of the Invention

The present invention relates generally to the manufacture of semiconductor devices. More particularly, the invention relates to a method of forming an epitaxial contact plug in a semiconductor device.

A claim of priority is made to Korean Patent Application No. 2004-90749 filed on Nov. 9, 2004, the disclosure of which is hereby incorporated by reference in its entirety.

2. Description of the Related Art

Static random access memory (SRAM) is a type of volatile memory used for temporary data storage in high performance computer applications. SRAM is known for its high speed of operation, low power consumption, and simple operation. Unlike dynamic random access memory (DRAM), data stored in SRAM does not have to be periodically refreshed.

A typical SRAM memory cell comprises a pair of cross coupled inverters for storing data, and a pair of transistors for controlling read and write access to the cell. Each of the cross coupled inverters comprises a pair of transistors. Hence, altogether an SRAM memory cell comprises six (6) transistors.

SRAM memory cells can be divided into three (3) general categories: complementary metal-oxide silicon (CMOS) type, high load resistor (HLR) type, and thin film transistor (TFT) type. The SRAM memory cells are assigned to the different categories according to different types of pull-up devices used in the cross coupled inverters.

For example, each inverter in a CMOS type SRAM memory cell comprises a positive metal-oxide semiconductor (PMOS) transistor with a first terminal connected to a power supply and a second terminal, and a negative metal-oxide semiconductor (NMOS) transistor with a first terminal connected to the second terminal of the PMOS transistor and a second terminal connected to ground. The PMOS transistors are used as pull-up devices and the NMOS transistors are used as pull-down devices.

HLR type SRAM memory cells use transistors including a high resistance polysilicon layer as the pull-up devices, and TFT type SRAM memory cells use P-type thin film transistors as the pull-up devices.

One attractive feature of TFT type SRAM memory cells is that they can be manufactured to be very small. This allows a large number of memory cells to be formed in a small area. In addition, TFT-type SRAM memory cells can be stacked on top of each other by placing an insulated substrate between them. This allows an even higher degree of integration.

Recently, CMOS type SRAM memory cells have been modified include stacked transistors. In particular, CMOS type SRAM memory cells have been formed with PMOS transistors stacked on top of NMOS transistors.

In a CMOS type SRAM memory cell formed with stacked transistors, two pairs of NMOS transistors are formed in a substrate and a pair of PMOS transistors are formed on top of the NMOS transistors. The two pairs of NMOS transistors comprise an access pair used to access the memory cell and a pull-down pair used as the pull-down devices. The PMOS transistors comprise the pull-up devices for the memory cell.

By including stacked transistors, the CMOS type SRAM memory cells achieve comparable levels of integration with the TFT type SRAM memory cells. In addition, the CMOS type cells are less susceptible to leakage current than the TFT type cells.

In CMOS type SRAM cells, an insulating interlayer is formed between the stacked PMOS and NMOS transistors and respective source/drain regions of the NMOS and PMOS transistors are electrically connected with each other by an epitaxial contact plug. The epitaxial contact plug is formed through a selective epitaxial growth (SEG) process and a chemical mechanical polishing (CMP) process.

FIGS. 1 to 3 are cross-sectional views illustrating a conventional method of forming a semiconductor memory device containing stacked transistors.

Referring to FIG. 1, a device isolation layer (not shown) is formed on a P-type semiconductor substrate 10 to define an active region 12. Semiconductor substrate 10 typically includes a silicon substrate such as a wafer. A first gate oxide layer (not shown), a first polysilicon layer, and a first silicide layer are sequentially formed on substrate 10 and a first gate electrode 14 is formed by sequentially patterning the first silicide oxide, polysilicon, and gate oxide layers. A silicon nitride layer is formed on substrate 10 to cover first gate electrode 14, and the silicon nitride layer is anisotropically etched until a top surface of substrate 10 is exposed to form a first gate spacer 16 on sidewalls of first gate electrode 14.

N+ type impurities are implanted in regions of substrate 10 exposed through gate first electrodes 14 and first gate spacers 16 to form a N+ doped source/drain region 18. As a result, a NMOS transistor is formed.

Referring to FIG. 2, an insulating interlayer 20b is formed on semiconductor substrate 10. Insulating interlayer 20b typically includes a highly fluid oxide layer such as a borophosphosilicate glass (BPSG) layer. A chemical mechanical polishing (CMP) process is performed on insulating interlayer 20b to planarize a top surface thereof.

A photoresist pattern is formed on insulating interlayer 20b by forming a photoresist film and then etching the photoresist film using a photolithography process. A portion of insulating interlayer 20b is then etched using the photoresist pattern as an etching mask to form an opening 22 exposing N+ doped source/drain region 18.

A selective epitaxial growth (SEG) process is performed on the surface of substrate 10 exposed through opening 22 to form a mushroom-shaped epitaxial plug 24. Epitaxial plug 24 is grown vertically in opening 22 from the surface of substrate 10 and horizontally along a top surface of insulating interlayer 20b to form a mushroom-shape having a head portion “A”.

Referring to FIG. 3, head portion “A” of epitaxial plug 24 is removed by a CMP process to expose the top surface of insulating interlayer 20b. As a result, an epitaxial contact plug 24a is formed in opening 22. A semiconductor pattern 26 contacting epitaxial contact plug 24a is then formed on insulating interlayer 20b.

A second gate oxide layer (not shown), a second polysilicon layer (not shown) and a second silicide layer (not shown) are sequentially formed on semiconductor pattern 26, and a second gate electrode 28 is formed by sequentially patterning the second silicide layer, the second polysilicon layer, and the second gate oxide layer. A silicon nitride layer is then formed on insulating interlayer 20b and semiconductor pattern 26 to cover second gate electrode 28, and the silicon nitride layer is anisotropically etched until top surfaces of insulating interlayer 20b and semiconductor pattern 26 are exposed. As a result, a second gate spacer 30 is formed on sidewalls of second gate electrode 28.

P+ type impurities are implanted in portions of semiconductor pattern 26 exposed through second gate electrodes 28 and second gate spacers 30 to form P+ type doped source/drain regions 32. Accordingly, a PMOS transistor is formed on semiconductor pattern 26.

Unfortunately, the CMP process used to form epitaxial contact plug 24a often causes defects in the semiconductor memory device.

For example, FIG. 4 is a cross-sectional view illustrating a defect caused by the CMP process used to form epitaxial contact plug 24a.

Referring to FIG. 4, when epitaxial plug 24 is polished by the CMP process, intense local stress is applied both sides of head portion “A”. The local stress may cause head portion “A” to separate from (e.g., “pop off”) epitaxial plug 24 together with a portion of etched insulating interlayer 20b. When separated from epitaxial plug 24, head portion “A” forms a lump 24b which may adhere to a surface of a pad in a CMP machine. By adhering to the surface of the CMP machine, lump 24b may scratch the surfaces of substrates polished by the CMP machine. The scratches can cause defects in the semiconductor memory devices, thereby decreasing the overall yield of the semiconductor manufacturing processes involving the CMP machine.

FIGS. 5 through 7 are images illustrating the number of scratches generated by CMP process during the manufacture of stacked transistors. FIGS. 5 and 6 illustrate the number of scratches generated by a CMP machine on a first semiconductor substrate, and FIG. 7 illustrate the number of scratches generated on a second semiconductor substrate by the same CMP machine after processing the first substrate. The number of scratches is measured after the PMOS transistors are formed. In FIGS. 5 to 7, dots on the image represent defective semiconductor devices. Accordingly, the dots are indicative of the number of scratches on each substrate by the CMP process.

FIG. 5 contains 6514 dots and FIG. 6 contains 2580 dots. These numbers represent enough defects to seriously deteriorate the devices' characteristics and lower the overall yield of semiconductor devices. FIG. 7 contains 740 dots—much fewer than FIGS. 5 and 6, but still enough to significantly reduce the yield of semiconductor devices and deteriorate device characteristics.

### SUMMARY OF THE INVENTION

According to one embodiment of the present invention, a method of forming an epitaxial contact plug in a semiconductor device comprising a semiconductor substrate and an insulating interlayer formed on the semiconductor substrate is provided. The method comprises forming a mushroom-shaped epitaxial plug on a portion of the semiconductor substrate exposed through an opening in the insulating interlayer using a selective epitaxial growth (SEG) process, forming a buffer layer on the insulating interlayer and the epitaxial plug, and planarizing the buffer layer and the epitaxial plug using a chemical mechanical polishing (CMP) process to expose a top surface of the insulating interlayer.

According to another embodiment of the present invention, a method of manufacturing a semiconductor device is provided. The method comprises forming an insulating interlayer on a semiconductor substrate, forming an opening in the insulating interlayer to expose source/drain regions of a transistor formed in the semiconductor substrate, forming a mushroom-shaped epitaxial plug on the source/drain regions using a selective epitaxial growth (SEG) process, forming a buffer layer on the insulating interlayer and the epitaxial plug, and planarizing the buffer layer and the epitaxial plug using a chemical mechanical polishing (CMP) process to expose a top surface of the insulating interlayer, thereby forming an epitaxial contact plug.

According to still another embodiment of the present invention, a method of manufacturing a semiconductor device is provided. The method comprises forming an insulating interlayer on a semiconductor substrate, forming an opening in the insulating interlayer to expose first source/drain regions in a lower transistor formed in the semiconductor substrate, forming a mushroom-shaped epitaxial plug on the first source/drain regions using a selective epitaxial growth (SEG) process, forming a buffer layer on the insulating interlayer and the epitaxial plug, and planarizing the buffer layer and the epitaxial plug using a chemical mechanical polishing (CMP) process to expose a top surface of the insulating interlayer, wherein the planarized epitaxial plug forms an epitaxial contact plug. The method further comprises forming a semiconductor pattern on the epitaxial contact plug in contact with the epitaxial contact plug, and forming an upper transistor on the semiconductor pattern.

### BRIEF DESCRIPTION OF THE DRAWINGS

The invention is described below in relation to several embodiments illustrated in the accompanying drawings. Throughout the drawings like reference numbers indicate like exemplary elements, components, or steps. In addition, the dimensions of layers and elements is exaggerated for clarity. In the drawings:

FIGS. 1 through 3 are cross-sectional views illustrating a conventional method of forming a semiconductor memory device having stacked transistors;

FIG. 4 is a cross-sectional view illustrating a defect caused by the conventional method illustrated in FIGS. 1 through 3;

FIGS. 5 through 7 are images illustrating the number of scratches caused by a CMP process in the conventional method illustrated in FIGS. 1 through 3;

FIGS. 8 through 11 are cross-sectional views illustrating a method of forming an epitaxial contact plug in a semiconductor memory device according to one embodiment of the present invention;

FIGS. 12 through 17 are cross-sectional views illustrating a method of manufacturing a semiconductor memory device according to an embodiment of the present invention; and,

FIGS. 18 through 26 are cross-sectional views illustrating a method of manufacturing a semiconductor memory device according to an exemplary embodiment of the present invention.

### DESCRIPTION OF EXEMPLARY EMBODIMENTS

Exemplary embodiments of the invention are described below with reference to the corresponding drawings. These embodiments are presented as teaching examples. The actual scope of the invention is defined by the claims that follow.

In the written description, the terms “on” and “onto” are used to indicate relative positions of layers and elements. For example, a layer formed “on” another layer may be formed either directly on top of the layer, or intervening layers may also be present.

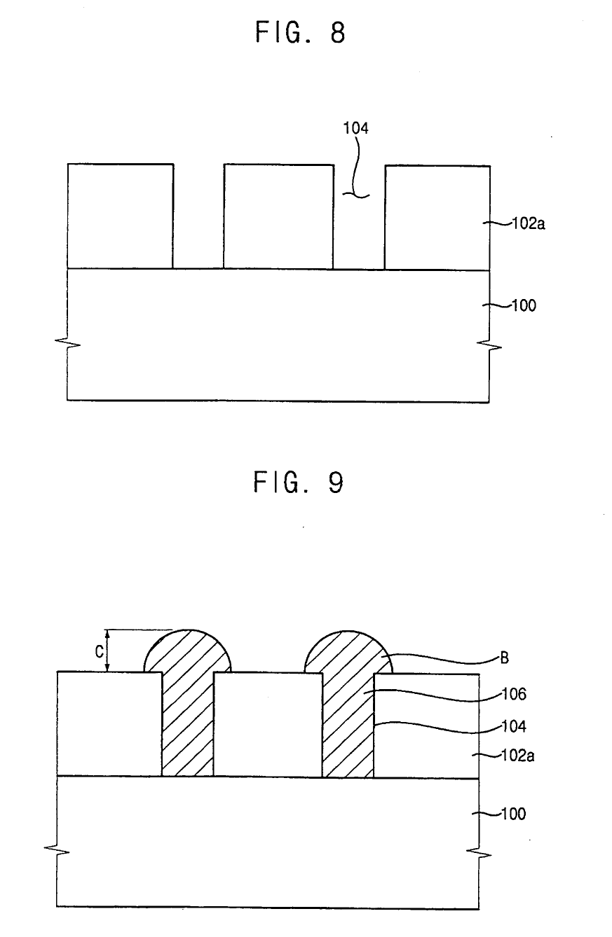

FIGS. 8 through 11 are cross-sectional views illustrating a method of forming an epitaxial contact plug in a semiconductor memory device according to an embodiment of the present invention.

Referring to FIG. 8, an insulating interlayer 102 (not shown) is formed on a semiconductor substrate 100. Insulating interlayer 102 typically comprises an oxide layer having a high fluidity such as borophosphosilicate glass (BPSG). A top surface of insulating interlayer 102 is generally planarized by a heat treatment and a chemical mechanical polishing (CMP) process.

A photoresist pattern is formed on insulating interlayer 102 by forming a photoresist film thereon and then etching the photoresist film using a photolithography process. Insulating interlayer 102 is etched using the photoresist pattern as an etching mask to form an etched insulating interlayer 102a having an opening 104 exposing a surface of substrate 100.

Referring to FIG. 9, a SEG process is performed on the surface of substrate 100 exposed through opening 104 to grow a mushroom-shaped epitaxial plug 106. Epitaxial plug 106 is grown vertically in opening 104 and then horizontally along a top surface of etched insulating interlayer 102a. As a result, epitaxial plug 106 has a head portion “B”. Head portion “B” has a thickness “C” from about 3000 Å to 4000 Å. Preferably, thickness “C” of head portion “B” is about 3.500 Å.

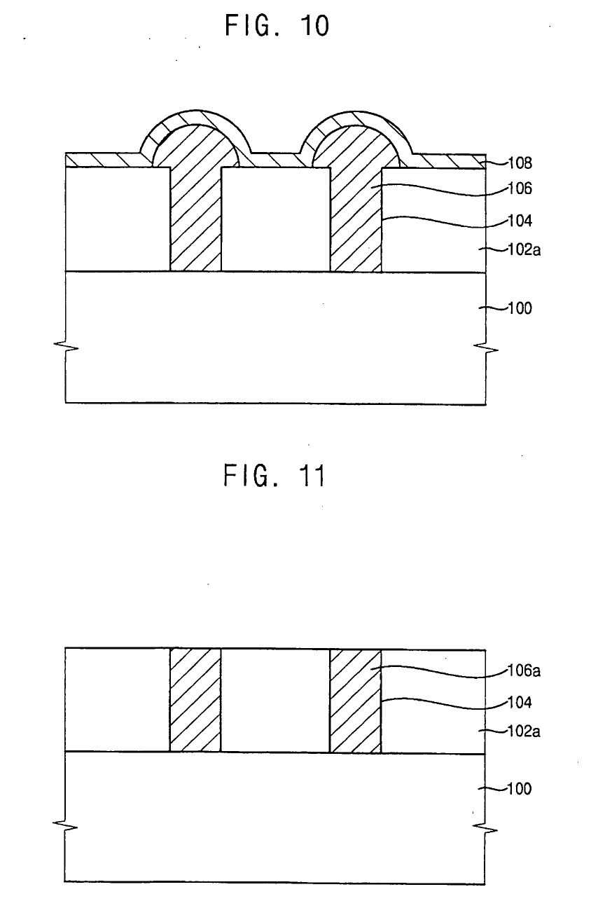

Referring to FIG. 10, a buffer layer 108 is formed on etched insulating interlayer 102a and epitaxial plug 106. Buffer layer 108 reduces the physical stress placed on head portion “B” in a CMP process used to planarize epitaxial plug 106. Buffer layer 108 is preferably formed of the same material as epitaxial plug 106. For example, buffer layer 108 may be formed of amorphous polysilicon, single crystalline silicon, doped polysilicon, or a combination of these materials. Buffer layer 108 is generally formed to a thickness of about 300 Å to 3000 Å. Preferably, buffer layer 108 is formed of amorphous polysilicon and is about 1500 Å thick.

Referring to FIG. 11, buffer layer 108 is removed and head portion “B” of epitaxial plug 106 is planarized by a CMP process until a top surface of etched insulating interlayer 102a is exposed. As a result, an epitaxial contact plug 106a is formed in opening 104.

For an abrasive, the CMP process uses a silica slurry including colloidal silica with suspended particles of diameters ranging from about 30 nm to 80 nm. The CMP process is performed with a membrane pressure of about 2.0 to 5.2 psi, a retainer ring pressure of about 2.5 psi to about 6.0 psi, and an inner tube pressure of about 2.0 psi to about 5.2 psi.

To perform the CMP process under relatively low pressure, the membrane pressure is set to about 2.0 psi, the retainer ring pressure is set to about 2.5 psi and the inner tube pressure is set to about 2.0 psi. To perform the CMP process under relatively high pressure, the membrane pressure is set to about 5.2 psi, the retainer ring pressure is set to about 6.0 psi, and the inner tube pressure is set to about 5.2 psi. Preferably, the CMP process is performed under relatively high pressure.

Using buffer layer 108 to reduce the physical stress placed on head portion “B” in the CMP process prevents head portion “B” from being separated from epitaxial plug 106 during the CMP process. Accordingly, scratches are prevented from forming on the semiconductor memory device and defects are prevented from occurring in the semiconductor memory device.

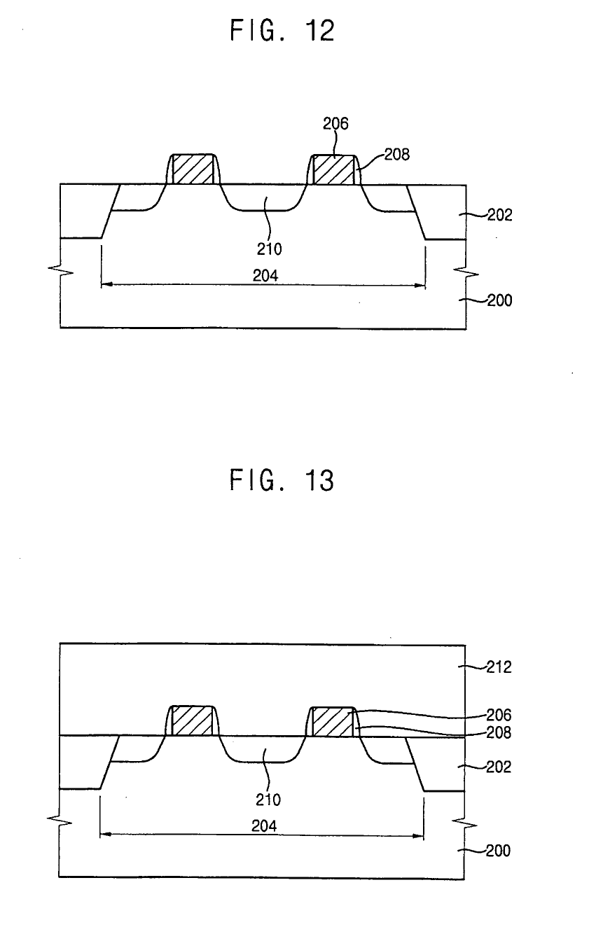

FIGS. 12 through 17 are cross-sectional views illustrating a method of manufacturing a semiconductor device according to an embodiment of the present invention. In the method illustrated in FIGS. 12 through 17, the method of FIGS. 8 through 11 is used to form an epitaxial contact plug.

Referring to FIG. 12, a device isolation layer 202 defining an active region 204 is formed on a semiconductor substrate 200. Device isolation layer 202 typically comprises an oxide layer referred to as a field oxide layer. Device isolation layer 202 is formed by a local oxidation silicon (LOCOS) process or a shallow trench isolation (STI) process.

A gate oxide layer (not shown) is formed on substrate 200, and a polysilicon layer and a silicide layer are sequentially formed on the gate oxide layer. A first gate electrode 206 is formed by sequentially patterning the silicide, polysilicon, and gate oxide layers. As a result, gate electrode 206 includes a conductive pattern comprising a polysilicon pattern and a silicide pattern.

A silicon nitride layer is formed on substrate 200 to cover gate electrode 206. The silicon nitride layer is anisotropically etched to expose a top surface of substrate 200 and form a gate spacer 208 on sidewalls of gate electrode 206.

Impurities are implanted in portions of substrate 200 exposed through gate electrodes 206 and gate spacers 208 to form a doped source/drain region 210.

Referring to FIG. 13, an insulating interlayer 212 (not shown) is formed on substrate 200 to cover gate electrode 206 and gate spacer 208. Insulating interlayer 212 includes an oxide layer having a high fluidity such as a BPSG layer. A heat treatment and then a CMP process are performed to planarize insulating interlayer 212.

Referring to FIG. 14, a photoresist film is formed on planarized insulating interlayer 212. The photoresist film is patterned by a photolithography process to form a photoresist pattern and the photoresist pattern is used as an etching mask in an etching process used to form an opening 214 exposing a top surface of substrate 200. Insulating interlayer 212 having opening 214 is referred to as etched insulating interlayer 212a.

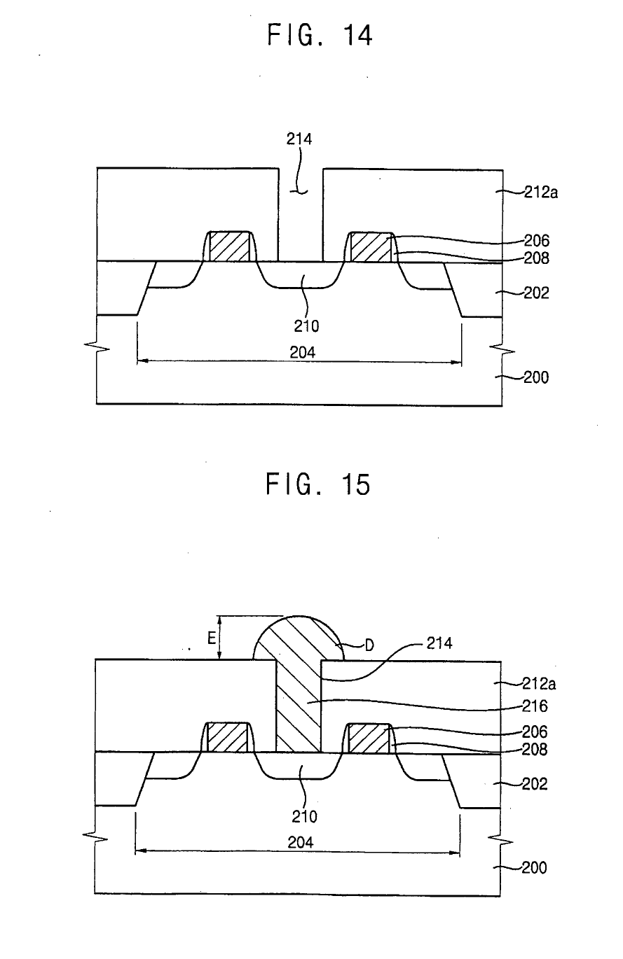

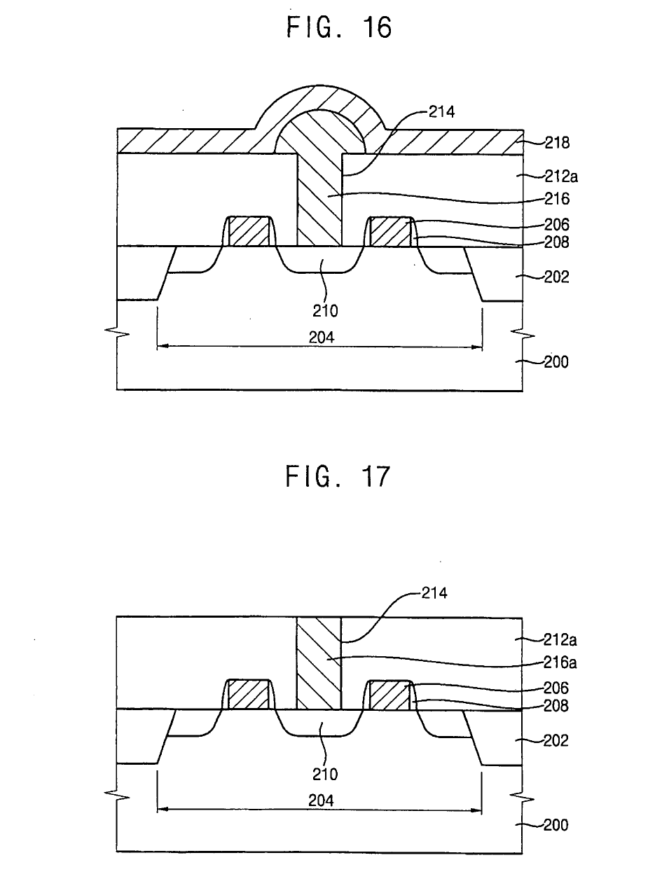

Referring to FIG. 15, a selective epitaxial growth (SEG) process is performed on source/drain region 210 exposed through opening 214 to form a mushroom-shaped epitaxial plug 216. Epitaxial plug 216 is grown vertically from the surface of source/drain region 210 and horizontally along a top surface of etched insulating interlayer 212a. As a result epitaxial plug 216 has a mushroom shape with a head portion “D”. A thickness “E” of head portion “D” is generally about 3000 Å to 4000 Å. Preferably, thickness “E” is about 3500 Å.

Although epitaxial plug 216 is typically formed in opening 214, a self-aligned contact (SAC) could also be formed in its place.

Referring to FIG. 16, a buffer layer 218 is formed on etched insulating interlayer 212a and epitaxial plug 216. Buffer layer 218 reduces the amount of physical stress placed on head portion “D” of epitaxial plug 216 when epitaxial plug 216 is planarized by a CMP process. Buffer layer 218 is preferably formed of the same material as epitaxial plug 216. For example, buffer layer 218 may include amorphous polysilicon, single crystalline silicon, doped polysilicon, or some combination thereof. Buffer layer 218 is typically formed with a thickness of about 300 Å to 3000 Å. Preferably, buffer layer 218 is formed of amorphous polysilicon and has a thickness of about 1500 Å.

Referring to FIG. 17, buffer layer 218 is removed and epitaxial plug 216 is planarized by a CMP process. The CMP process exposes a top surface of etched insulating interlayer 212a to form an epitaxial contact plug 216a in opening 214.

For an abrasive, the CMP process uses a silica slurry including colloidal silica with suspended particles of diameters ranging from about 30 nm to 80 nm. The CMP process is performed with a membrane pressure of about 2.0 to 5.2 psi, a retainer ring pressure of about 2.5 psi to about 6.0 psi, and an inner tube pressure of about 2.0 psi to about 5.2 psi.

To perform the CMP process under relatively low pressure, the membrane pressure is set to about 2.0 psi, the retainer ring pressure is set to about 2.5 psi and the inner tube pressure is set to about 2.0 psi. To perform the CMP process under relatively high pressure, the membrane pressure is set to about 5.2 psi, the retainer ring pressure is set to about 6.0 psi, and the inner tube pressure is set to about 5.2 psi. Preferably, the CMP process is performed under relatively high pressure.

Using buffer layer 208 to reduce the physical stress placed on head portion “D” in the CMP process prevents head portion “D” from being separated from epitaxial plug 206 during the CMP process. Accordingly, scratches are prevented from forming on the semiconductor memory device and defects are prevented from occurring in the semiconductor memory device.

FIGS. 18 to 26 are cross-sectional views illustrating a method of manufacturing a semiconductor memory device including stacked transistors according to an exemplary embodiment of the present invention.

Referring to FIG. 18, a device isolation layer (not shown) defining an active region 302 is formed on a P-type semiconductor substrate 300. Semiconductor substrate 300 typically comprises a semiconductor wafer, and the device isolation layer typically comprises an oxide layer such as field oxide layer. The field oxide layer is generally formed by either a local oxidation silicon (LOCOS) process or a shallow trench isolation (STI) process.

A first gate oxide layer (not shown) is formed on substrate 300, and a first polysilicon layer and a first silicide layer are sequentially formed on the first gate oxide layer. The first silicide layer, the first polysilicon layer, and the first gate oxide layer are sequentially patterned to form a first gate electrode 304. Accordingly, first gate electrode 304 includes a conductive pattern (not shown) comprising a polysilicon pattern (not shown) and a silicide pattern (not shown).

A silicon nitride layer is formed on the substrate 300 to cover first gate electrode 304. The silicon nitride layer is anisotropically etched to expose a top surface of substrate 300, thereby forming a first gate spacer 306 on sidewalls of first gate electrode 304.

N+ type impurities are implanted in portions of substrate 300 exposed through first gate electrode 304 and first gate spacers 306 to form a N+ doped source/drain region 308. N+ doped source/drain region 308 completes an NMOS transistor functioning as pull down device in the semiconductor memory device.

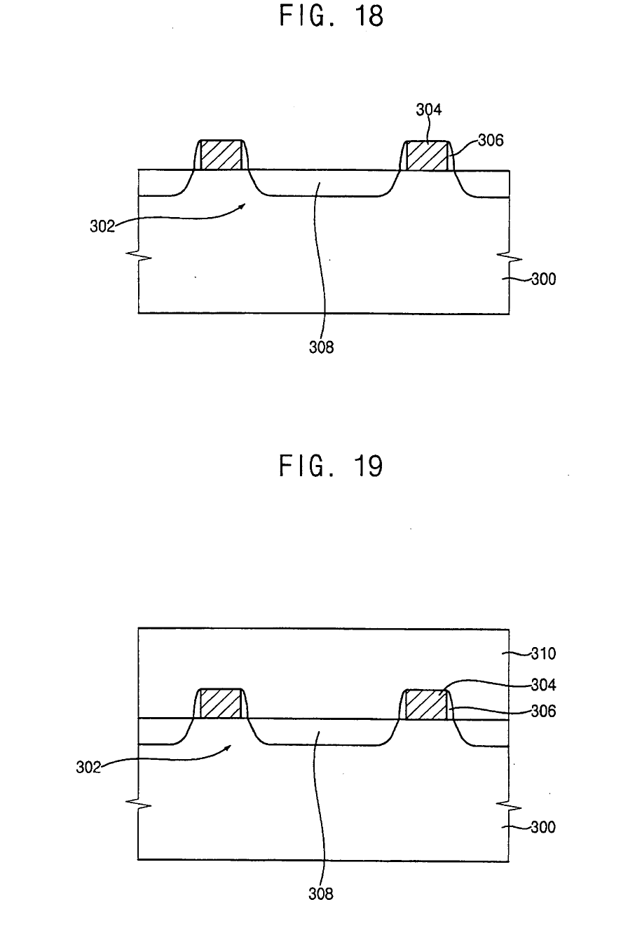

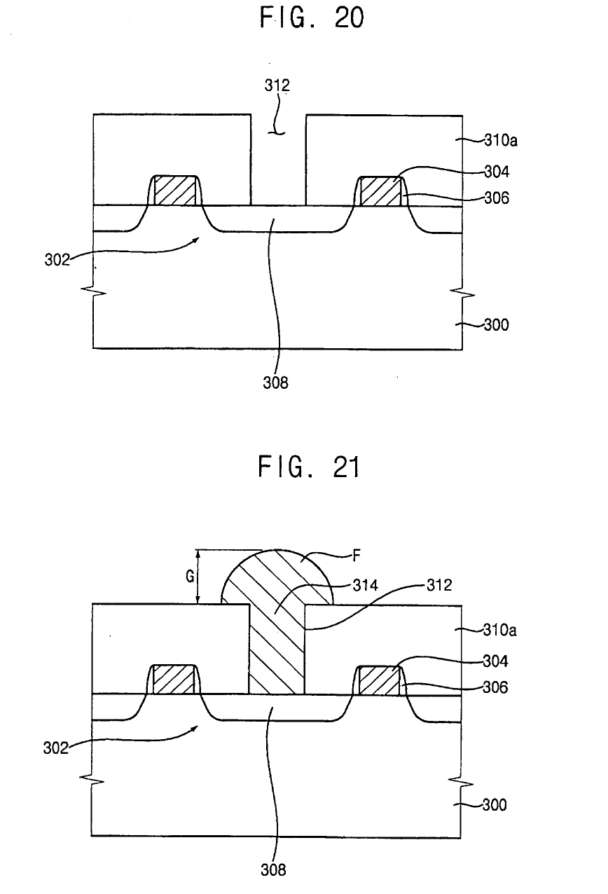

Referring to FIG. 19, an insulating interlayer 310 is formed on semiconductor substrate 300 to cover first gate electrodes 304 and first gate spacer 306. Insulating interlayer 310 includes a highly fluid oxide layer such as a borophosphosilicate glass (BPSG) layer. A heat treatment and then a CMP process are performed on insulating interlayer 310 to planarize the top surface thereof.

Referring to FIG. 20, a photoresist pattern is formed on insulating interlayer 310 by first forming a photoresist film (not shown) and then patterning the photoresist film using a photolithography process. Insulating interlayer 310 is etched using the photoresist pattern as an etching mask, to form an opening 312 exposing N+ doped source/drain region 308. Insulating interlayer 310 containing opening 312 is referred to as an etched insulating interlayer 310a.

Referring to FIG. 21, a selective epitaxial growth (SEG) process is performed on source/drain region 308 exposed through opening 312 to form a mushroom-shaped epitaxial plug 314 having a head portion “F”. Epitaxial plug 314 grows vertically in opening 312, and horizontally along a top surface of etched insulating interlayer 310a. Head portion “F” has a thickness “G” ranging from about 3000 Å to 4000 Å. Preferably, thickness “G” is about 3500 Å.

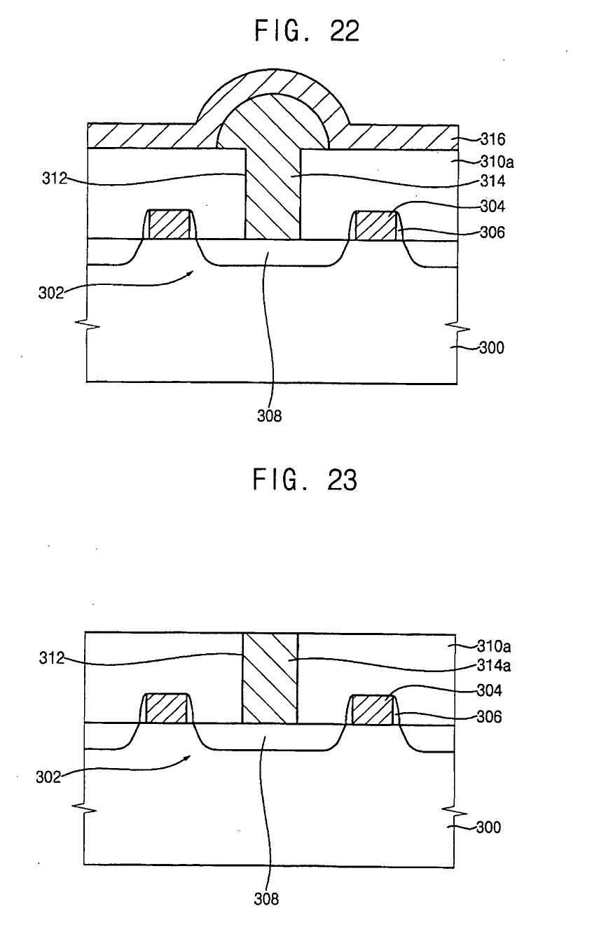

Referring to FIG. 22, a buffer layer 316 is formed on etched insulating interlayer 310a and epitaxial plug 314 to reduce local stress placed on side portions of head portion “F” during a CMP process. Buffer layer 316 is typically formed of the same material as epitaxial plug 314. For example, buffer layer 316 may be formed of amorphous polysilicon, single crystalline silicon, doped polysilicon, or a combination of these. Buffer layer 316 typically has a thickness of about 300 Å to 3000 Å. Preferably, buffer layer 316 is formed of amorphous polysilicon and has a thickness of about 1500 Å.

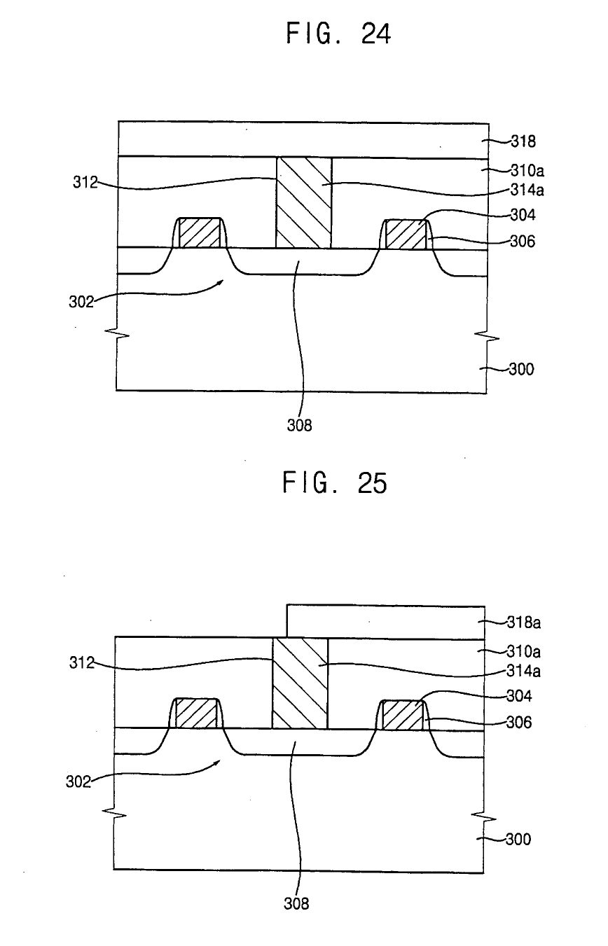

Referring to FIG. 23, buffer layer 316 is removed and epitaxial plug 314 is planarized by a CMP process until a top surface of etched insulating interlayer 310a is exposed. As a result, an epitaxial contact plug 314a is formed in opening 312.

For an abrasive, the CMP process uses a silica slurry including colloidal silica with suspended particles of diameters ranging from about 30 nm to 80 nm. The CMP process is performed with a membrane pressure of about 2.0 to 5.2 psi, a retainer ring pressure of about 2.5 psi to about 6.0 psi, and an inner tube pressure of about 2.0 psi to about 5.2 psi.

To perform the CMP process under relatively low pressure, the membrane pressure is set to about 2.0 psi, the retainer ring pressure is set to about 2.5 psi and the inner tube pressure is set to about 2.0 psi. To perform the CMP process under relatively high pressure, the membrane pressure is set to about 5.2 psi, the retainer ring pressure is set to about 6.0 psi, and the inner tube pressure is set to about 5.2 psi. Preferably, the CMP process is performed under relatively high pressure.

Once epitaxial contact plug 314a is formed, a storage capacitor and a wiring are formed over epitaxial contact plug 314a.

Because buffer layer 316 prevents head portion “F” from being separated from epitaxial plug 314 during the CMP process the number of scratches formed on the semiconductor memory device is minimized.

Referring to FIG. 24, a semiconductor layer 318 is formed on epitaxial contact plug 314a and etched insulating interlayer 310a. Semiconductor layer 318 is typically formed of single crystalline silicon.

Referring to FIG. 25, a photoresist pattern is formed on semiconductor layer 318 by first forming a photoresist film and then patterning the photoresist film by a photolithography process. Semiconductor layer 318 is etched using the photoresist pattern as an etching mask to form a semiconductor pattern 318a on etched insulating interlayer 310a and epitaxial contact plug 314a. In a subsequent process, a PMOS transistor is formed on semiconductor pattern 318a.

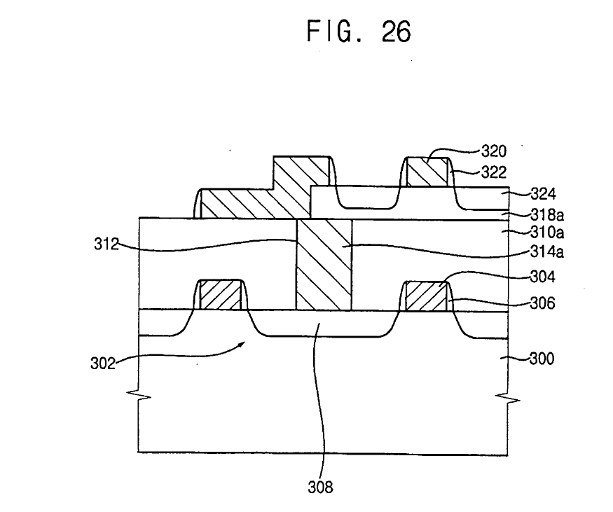

Referring to FIG. 26, a second gate oxide layer (not shown), a second polysilicon layer (not shown) and a second silicide layer (not shown) are sequentially formed on semiconductor pattern 318a and etched insulating interlayer 310a. Second silicide layer, second polysilicon layer, and second gate oxide layer are sequentially etched to form a second gate electrode 320.

A silicon nitride layer is formed on etched insulating interlayer 310a and semiconductor pattern 318a to cover second gate electrode 320. The silicon nitride layer is anisotropically etched until top surfaces of etched insulating interlayer 310a and semiconductor pattern 318a are exposed. As a result, a second gate spacer 322 is formed on sidewalls of second gate electrode 320.

P+ type impurities are implanted in portions of semiconductor pattern 318a exposed through second gate electrodes 320 and second gate spacers 322 to form a P+ doped source/drain region 324. P+ doped source/drain region 324 completes a PMOS transistor functioning as a pull-up device. The PMOS transistor is formed over the NMOS transistor to complete a pair of stacked transistors in the semiconductor memory device.

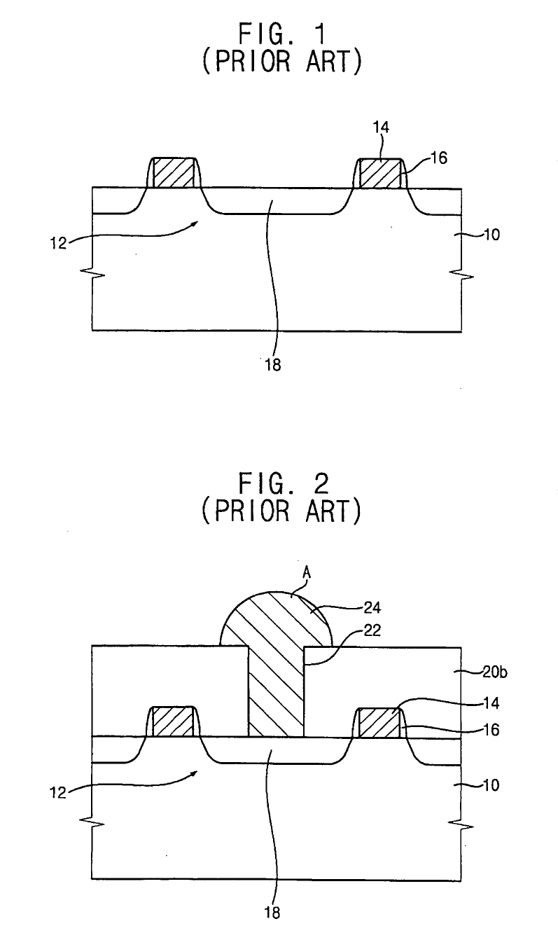

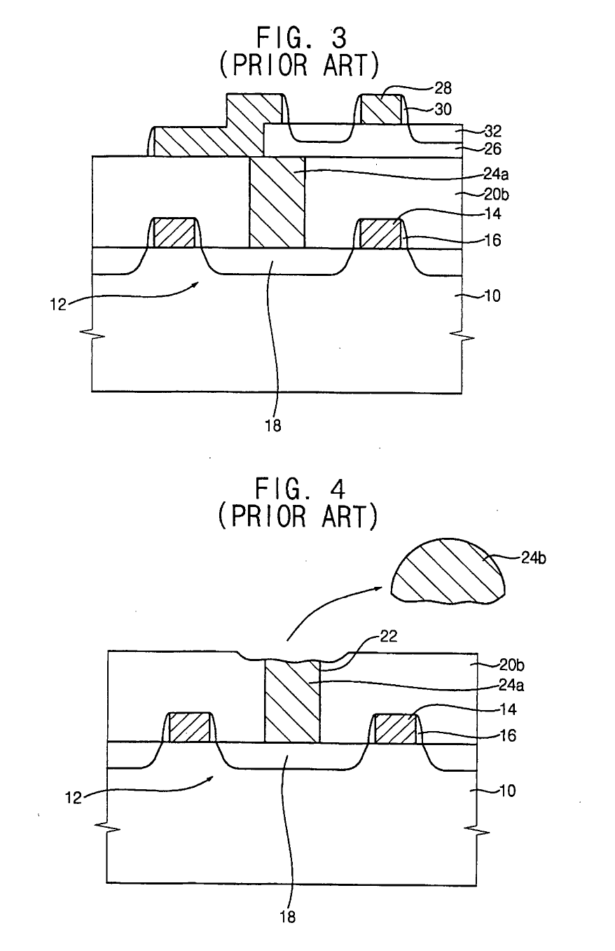

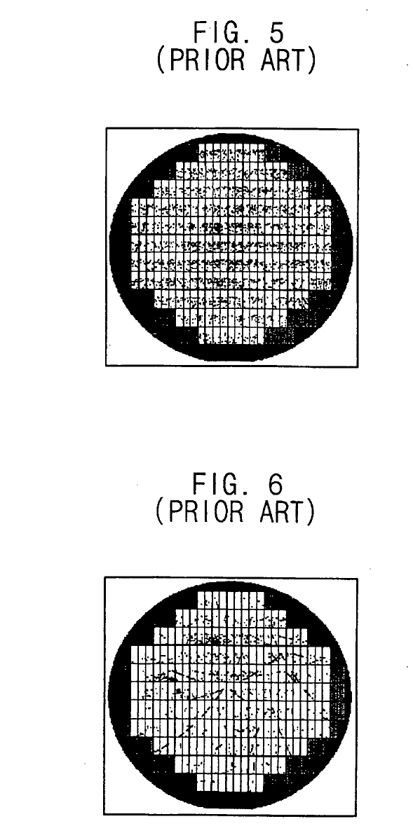

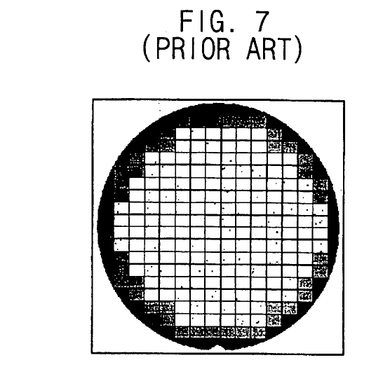

Experiments were performed to determine the number of defects generated in semiconductor devices under different processing conditions. In the experiments, the semiconductor devices were formed with stacked transistors using either the conventional method illustrated in FIGS. 1 through 3, or the method illustrated in FIGS. 18 through 26. Where the semiconductor devices were formed using the method of FIGS. 18 to 26, buffer layer 316 was formed of an amorphous polysilicon layer with a thickness of approximately 1500 Å.

In the experiments, the pressure and the duration of the CMP process was also varied to observe the resulting effects on the number of defects in the semiconductor devices.

The number of the scratches in the semiconductor devices was measured after the semiconductor devices were completely formed.

Table 1 shows the CMP processing conditions and the number of the scratches measured in each experiment.

TABLE 1

| | CMP Process | | | |
|---|---|---|---|---|
| | | | Time | Number |
| | Buffer layer | Pressure | (sec) | of scratch |
| Experiment 1 | Amorphous polysilicon, | High | 75 | 0 |
| | 1500 Å | | | |
| Experiment 2 | Amorphous polysilicon, | Low | 180 | 6 |
| | 1500 Å | | | |
| Experiment 3 | No buffer layer | Low | 60 | 338 |
| Experiment 4 | No buffer layer | High | 15 | 569 |

As shown in Table 1, when the buffer layer is used, the number of scratches on the wafer is relatively small regardless of the CMP processing conditions. Where no buffer layer is formed on the wafer, the number of the scratch is sufficiently large to deteriorate operating characteristics of semiconductor devices even when the CMP process is performed at a relatively low pressure for a relatively long time.

Embodiments of the invention use a buffer layer to prevent scratches from occurring on semiconductor devices. In the absence of the buffer layer, scratches may be caused by a head portion of an epitaxial contact plug that is separated from an insulating interlayer during a CMP process and then adheres to a CMP machine performing the CMP process. The buffer layer serves to reduce local stress on the epitaxial plug so that the head portion does not “pop off” during the CMP process. By preventing scratches from occurring on the semiconductor devices, the associated device characteristics and semiconductor device yield is generally improved.

The foregoing preferred embodiments are teaching examples. Those of ordinary skill in the art will understand that various changes in form and details may be made to the exemplary embodiments without departing from the scope of the present invention which is defined by the following claims.

What is claimed:

1. A method of forming an epitaxial contact plug in a semiconductor device comprising a semiconductor substrate and an insulating interlayer formed on the semiconductor substrate, the method comprising:
forming a mushroom-shaped epitaxial plug on a portion of the semiconductor substrate exposed through an opening in the insulating interlayer using a selective epitaxial growth (SEG) process;
forming a buffer layer on the insulating interlayer and the epitaxial plug; and,
planarizing the buffer layer and the epitaxial plug using a chemical mechanical polishing (CMP) process to expose a top surface of the insulating interlayer.

2. The method of claim 1, wherein the mushroom-shaped epitaxial plug has a head portion with a height of about 3000 Å to 4000 Å.

3. The method of claim 1, wherein the buffer layer is formed of amorphous polysilicon, single crystalline silicon, doped polysilicon, or a combination thereof.

4. The method of claim 1, wherein the buffer layer has a thickness of about 300 Å to 3000 Å.

5. The method of claim 1, wherein the CMP process uses an abrasive comprising a silica slurry including colloidal silica with suspended particles of diameters ranging from about 30 nm to 80 nm; and,
wherein the CMP process is performed with a membrane pressure of about 2.0 psi to 5.2 psi, a retainer ring pressure of about 2.5 psi to 6.0 psi, and an inner tube pressure of about 2.0 psi to about 5.2 psi.

6. The method of claim 1, wherein the epitaxial contact plug connects a negative metal-oxide semiconductor (NMOS) transistor to a positive metal-oxide semiconductor (PMOS) transistor.

7. A method of manufacturing a semiconductor device, the method comprising:
forming an insulating interlayer on a semiconductor substrate;
forming an opening in the insulating interlayer to expose source/drain regions of a transistor formed in the semiconductor substrate;
forming a mushroom-shaped epitaxial plug on the source/drain regions using a selective epitaxial growth (SEG) process;
forming a buffer layer on the insulating interlayer and the epitaxial plug; and,
planarizing the buffer layer and the epitaxial plug using a chemical mechanical polishing (CMP) process to expose a top surface of the insulating interlayer, thereby forming an epitaxial contact plug.

8. The method of claim 7, wherein the epitaxial plug has a head portion with a height of about 3000 Å to 4000 Å.

9. The method of claim 7, wherein the buffer layer is formed of amorphous polysilicon, single crystalline silicon, doped polysilicon or a combination thereof.

10. The method of claim 7, wherein the buffer layer has a thickness of about 300 Å to 3000 Å.

11. The method of claim 7, wherein the CMP process uses an abrasive comprising a silica slurry including colloidal silica with suspended particles of diameters ranging from about 30 nm to 80 nm; and,
wherein the CMP process is performed with a membrane pressure of about 2.0 psi to 5.2 psi, a retainer ring pressure of about 2.5 psi to 6.0 psi, and an inner tube pressure of about 2.0 psi to about 5.2 psi.

12. The method of claim 7, wherein the epitaxial contact plug connects the source/drain regions to another transistor.

13. A method of manufacturing a semiconductor device, the method comprising:
forming an insulating interlayer on a semiconductor substrate;
forming an opening in the insulating interlayer to expose first source/drain regions in a lower transistor formed in the semiconductor substrate;
forming a mushroom-shaped epitaxial plug on the first source/drain regions using a selective epitaxial growth (SEG) process;
forming a buffer layer on the insulating interlayer and the epitaxial plug;
planarizing the buffer layer and the epitaxial plug using a chemical mechanical polishing (CMP) process to expose a top surface of the insulating interlayer, wherein the planarized epitaxial plug forms an epitaxial contact plug;
forming a semiconductor pattern on the epitaxial contact plug in contact with the epitaxial contact plug; and, forming an upper transistor on the semiconductor pattern.

14. The method of claim 13, wherein forming the semiconductor pattern comprises:
forming a semiconductor layer on the epitaxial contact plug and the insulating interlayer; and,
patterning the semiconductor layer.

15. The method of claim 14, wherein the semiconductor layer comprises single crystalline silicon.

16. The method of claim 13, wherein the epitaxial plug has a head portion with a height of about 3000 Å to 4000 Å.

17. The method of claim 13, wherein the buffer layer is formed of amorphous polysilicon, single crystalline silicon, doped polysilicon, or a combination thereof.

18. The method of claim 13, wherein the buffer layer has a thickness of about 300 Å to 3000 Å.

19. The method of claim 13, wherein the CMP process uses an abrasive comprising a silica slurry including colloidal silica with suspended particles of diameters ranging from about 30 nm to 80 nm; and,
wherein the CMP process is performed with a membrane pressure of about 2.0 psi to 5.2 psi, a retainer ring pressure of about 2.5 psi to 6.0 psi, and an inner tube pressure of about 2.0 psi to about 5.2 psi.

20. The method of claim 13, wherein the lower transistor is a negative metal-oxide semiconductor (NMOS) transistor and the upper transistor is a positive metal-oxide semiconductor (PMOS) transistor.
